(19) United States
(12) Patent Application Publication
(10) Pub. No.: US 2024/0145385 A1
(43) Pub. Date: May 2, 2024

(54) MEMORY DEVICES WITH ROW-BASED CONFIGURED SUPPLY VOLTAGES

(71) Applicant: Taiwan Semiconductor Manufacturing Company, Ltd., Hsinchu (TW)

(72) Inventors: Yi-Hsin Nien, Hsinchu City (TW); Hidehiro Fujiwara, Hsinchu City (TW); Chih-Yu Lin, Taichung City (TW); Yen-Huei Chen, Jhudong Township (TW)

(73) Assignee: Taiwan Semiconductor Manufacturing Company, Ltd., Hsinchu (TW)

(21) Appl. No.: 18/170,443

(22) Filed: Feb. 16, 2023

Related U.S. Application Data
(60) Provisional application No. 63/419,962, filed on Oct. 27, 2022.

(51) Int. Cl. H01L 23/528; H01L 25/18; H10B 10/00; H10B 80/00

(52) U.S. Cl. CPC H01L 23/5283; H01L 25/18; H10B 10/125; H10B 80/00

(57) ABSTRACT

A memory device includes a plurality of memory cells disposed over a substrate and formed as an array that has a plurality of rows and a plurality of columns. Each of the plurality of memory cells includes a plurality of transistors. A first subset of the plurality of memory cells, that are disposed in first neighboring ones of the plurality of rows, are physically coupled to a corresponding one of a plurality of second interconnect structures that carries a supply voltage through a corresponding one of a plurality of first interconnect structures. The plurality of first interconnect structures extend along a first lateral direction in parallel with a lengthwise direction of a channel of each of the transistors of the memory cells, and the plurality of second interconnect structures, disposed above the plurality of first interconnect structures, extend along a second lateral direction perpendicular to the first lateral direction.

### CROSS-REFERENCE TO RELATED APPLICATIONS

This application claims priority to and the benefit of U.S. Patent App. No. 63/419,962, filed Oct. 27, 2022, the entire disclosure of which is incorporated herein by reference.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an example circuit diagram of a memory cell, in accordance with some embodiments.

FIG. 2 illustrates an example circuit diagram of a memory array having a number of the memory cells of FIG. 1, in accordance with some embodiments.

FIG. 3 illustrates an example layout of the memory cell of FIG. 1, in accordance with some embodiments.

FIG. 4 illustrates a portion of the example layout of FIG. 3, in accordance with some embodiments.

FIG. 5 illustrates an example layout including a number of the example layouts of FIG. 3, in accordance with some embodiments.

FIG. 6 illustrates a cross-sectional view of a portion of a semiconductor device, in accordance with some embodiments.

FIG. 7 illustrates an example circuit diagram of a memory device, in accordance with some embodiments.

FIG. 8 illustrates example supply voltages received by the memory device of FIG. 7, in accordance with some embodiments.

FIG. 9 illustrates an example circuit diagram of a memory device, in accordance with some embodiments.

FIG. 10 illustrates example supply voltages received by the memory device of FIG. 9, in accordance with some embodiments.

FIG. 11 illustrates an example circuit diagram of a memory device, in accordance with some embodiments.

FIG. 12 illustrates a portion of an example layout of the memory device of FIG. 11, in accordance with some embodiments.

FIG. 13 illustrates an example circuit diagram of a memory device, in accordance with some embodiments.

FIG. 14 illustrates example supply voltages received by the memory device of FIG. 13, in accordance with some embodiments.

FIG. 15 illustrates an example circuit diagram of a memory device, in accordance with some embodiments.

FIG. 16 illustrates example supply voltages received by the memory device of FIG. 15, in accordance with some embodiments

FIG. 17 illustrates an example circuit diagram of a memory device, in accordance with some embodiments.

FIG. 18 illustrates a portion of an example layout of the memory device of FIG. 17, in accordance with some embodiments.

FIG. 19 illustrates a flowchart of a method for forming a memory device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A common type of integrated circuit memory is a static random access memory (SRAM) device. A typical SRAM memory device has an array of memory cells, or “bit-cells.” In some examples, each memory cell uses six transistors connected between an upper reference potential and a lower reference potential (typically ground) such that one of two storage nodes can be occupied by the information to be stored, with the complementary information stored at the other storage node. Each bit in the SRAM cell is stored on four of the transistors, which form two cross-coupled inverters. The other two transistors are connected to the memory cell word line to control access to the memory cell during read and write operations by selectively connecting the bit cell to its bit lines.

Typically, an SRAM device has an array of memory cells that include transistors formed using a fin field effect transistor (FinFET) architecture or a gate-all-around (GAA) transistor architecture. For example in a FinFET architecture, a polysilicon/metal structure can be connected to a semiconductor fin that extends above an isolation material. The polysilicon/metal structure functions as the gate of a corresponding FinFET transistor such that a voltage applied to the gate determines the flow of electrons between source/drain (S/D) contacts connected to the fin on opposite sides of the gate. A threshold voltage of the FinFET transistor is the minimum voltage for the transistor considered to be turned “on” such that an appreciable current can flow between the S/D contacts. The number of gates in contact with a fin along its lengthwise direction that are used in forming a SRAM cell can sometimes be referred to as a “pitch,” often termed a “contacted polysilicon pitch” or “CPP,” of the SRAM cell along one dimension and is at least partially determinative of the density of the SRAM device.

For example, a two contacted poly pitch (2CPP) SRAM cell includes two pass gate transistors, two PMOS transistors, and two NMOS transistors that are collectively formed using a number of active regions (e.g., fins), the active regions having two gates (e.g., polysilicon or metal structures) connected thereto along its lengthwise direction and having a S/D contact connected to the active region between at least some of the gates. In the manufacture of typical 2CPP SRAM architectures, a process step requiring a cut of a portion of the fins in each cell is necessary to form a 6T SRAM cell. In addition, the memory cells arranged along neighboring rows typically share the same source/drain contact structure, which disadvantageously limits the capability for independently controlling (e.g., accessing) one or more certain rows. For example, in the 2CPP SRAM architectures, the neighboring cells typically rely on the shared source/drain contact structure to receive a supply voltage (e.g., cell VDD or CVDD). In certain scenarios, if the supply voltage is desired to be altered for some of the rows, it is significantly challenging using the 2CPP SRAM architectures. Thus, the existing SRAM devices have not been entirely satisfactory in many aspects.

The present disclosure provides various embodiments of a memory device (e.g., an SRAM array) configured in a 4CPP architecture and designed to resolve the above-identified technical issues. In various embodiments, the memory device, as disclosed herein, are constructed in the 4CPP architecture where, for each memory cell of the disclosed memory device, there are four gates in contact with each of the active regions. With such a 4CPP architecture, the memory cells arranged along neighboring rows can be operatively coupled to a supply voltage (e.g., VDD) through respectively interconnect structures. As such, respective supply voltages (e.g., CVDD) received by different rows of the memory cells can be independently configured. For example, a first supply voltage (e.g., CVDD1) received by a first row of the memory cells can be boosted to improve write operation on the first row of memory cells, while a second supply voltage (e.g., CVDD2) received by a second row of the memory cells may remain unchanged (e.g., equal to VDD). In another example, a first supply voltage (e.g., CVDD1) received by a first row of the memory cells, which are not selected for being accessed, can be decreased to save power, while a second supply voltage (e.g., CVDD2) received by a second row of the memory cells, which are selected for being accessed, may remain unchanged (e.g., equal to VDD).

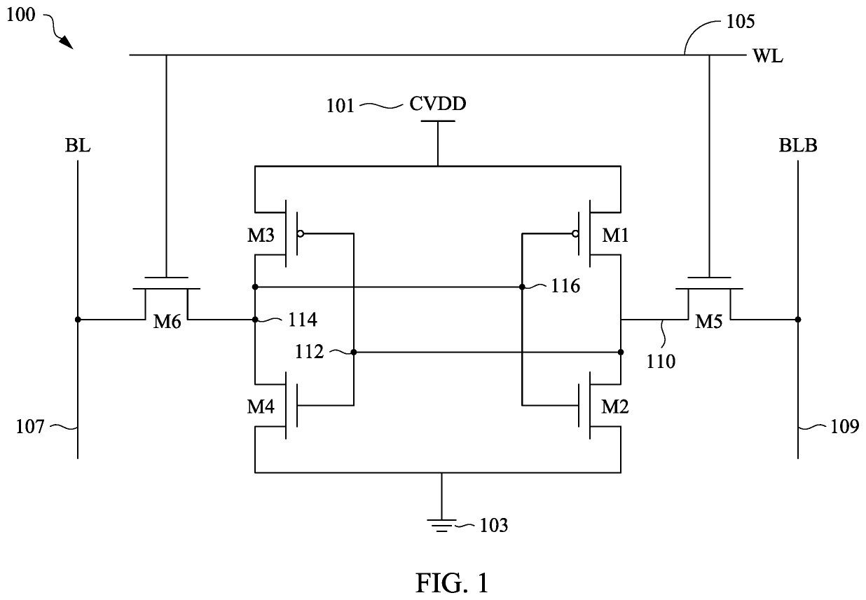

Referring to FIG. 1, an example circuit diagram of a memory cell (a memory bit, or a bit cell) 100 is illustrated. In accordance with some embodiments of the present disclosure, the memory cell 100 is configured as a static random access memory (SRAM) cell that includes a number of transistors. For example in FIG. 1, the memory cell 100 includes a six-transistor (6T)-SRAM cell. Each of the transistors may be formed in a nanostructure transistor configuration, which shall be discussed in further detail below. In some other embodiments, the memory cell 100 may be implemented as any of a variety of other SRAM cells such as, for example, a two-transistor-two-resistor (2T-2R) SRAM cell, a four-transistor (4T)-SRAM cell, an eight-transistor (8T)-SRAM cell, a ten-transistor (10T)-SRAM cell, etc. Further, although the discussion of the current disclosure is directed to an SRAM cell, it is understood that other embodiments of the current disclosure can also be used in any of the memory cells such as, for example, dynamic random access (DRAM) memory cells.

As shown in FIG. 1, the memory cell 100 includes 6 transistors: M1, M2, M3, M4, M5, and M6. The transistors M1 and M2 are formed as a first inverter and the transistors M3 and M4 are formed as a second inverter, wherein the first and second inverters are cross-coupled to each other. Specifically, the first and second inverters are each coupled between first voltage reference (or first supply voltage) 101 and second voltage reference (or second supply voltage) 103. In some embodiments, the first voltage reference 101 is a voltage level of a supply voltage applied to the memory cell 100, which is typically referred to as “CVDD.” The second voltage reference 103 is typically referred to as “ground.” The first inverter (formed by the transistors M1 and M2) is coupled to the transistor M5, and the second inverter (formed by the transistors M3 and M4) is coupled to the transistor M6. In addition to being coupled to the first and second inverters, the transistors M6 and M5 are each coupled to a word line (WL) 105 and are coupled to a bit line (BL) 107 and a complementary bit line 109 (sometimes referred to as bit line bar or BLB), respectively.

In some embodiments, the transistors M1 and M3 are referred to as pull-up transistors of the memory cell 100 (hereinafter “pull-up transistor M1” and “pull-up transistor M3,” respectively); the transistors M2 and M4 are referred to as pull-down transistors of the memory cell 100 (hereinafter “pull-down transistor M2” and “pull-down transistor M4,” respectively); and the transistors M5 and M6 are referred to as access transistors of the memory cell 100 (hereinafter “access transistor M5” and “access transistor M6,” respectively). In some embodiments, the transistors M2, M4, M5, and M6 each includes an n-type metal-oxide-semiconductor (NMOS) transistor, and M1 and M3 each includes a p-type metal-oxide-semiconductor (PMOS) transistor. Although the illustrated embodiment of FIG. 1 shows that the transistors M1-M6 are either NMOS or PMOS transistors, any of a variety of transistors or devices that are suitable for use in a memory device may be implemented as at least one of the transistors M1-M6 such as, for example, a bipolar junction transistor (BJT), a high-electron-mobility transistor (HEMT), etc.

The access transistors M5 and M6 each has a gate coupled to the WL 105. The gates of the transistors M5 and M6 are configured to receive a pulse signal, through the WL 105, to allow or block an access of the memory cell 100 accordingly, which will be discussed in further detail below. The transistors M2 and M5 are coupled to each other at node 110 with the transistor M2's drain and the transistor M5's source. The node 110 is further coupled to a drain of the transistor M1 and node 112. The transistors M4 and M6 are coupled to each other at node 114 with the transistor M4's drain and the transistor M6's source. The node 114 is further coupled to a drain of the transistor M3 and node 116.

When a memory cell (e.g., the memory cell 100) stores a data bit, a first node of the bit cell is configured to be at a first logical state (either a logical 1 or a logical 0), and a second node of the bit cell is configured to be at a second logical state (either a logical 0 or a logical 1). The first and second logical states are complementary with each other. In some embodiments, the first logical state at the first node may represent the logical state of the data bit stored in the memory cell. For example, in the illustrated embodiment of FIG. 1, when the memory cell 100 store a data bit at a logical 1 state, the node 110 is configured to be at the logical 1 state, and the node 114 is configured to be at the logical 0 state.

To read the logical state of the data bit stored in the memory cell 100, the BL 107 and BLB 109 are pre-charged to CVDD (e.g., a logical high, e.g., using a capacitor to hold the charge). Then the WL 105 is asserted, or activated, by an assert signal to a logical high, which turns on the access transistors M5 and M6. Specifically, a rising edge of the assert signal is received at the gates of the access transistors M5 and M6, respectively, so as to turn on the access transistors M5 and M6. Once the access transistors M5 and M6 are turned on, based on the logical state of the data bit, the pre-charged BL 107 or BLB 109 may start to be discharged. For example, when the memory cell 100 stores a logical 0, the node 114 (e.g., Q) may present a voltage corresponding to the logical 1, and the node 110 (e.g., Q bar) may present a voltage corresponding to the complementary logical 0. In response to the access transistors M5 and M6 being turned on, a discharge path, starting from the pre-charged BLB 109, through the access transistor M5 and pull-down transistor M2, and to ground 103, may be provided. While the voltage level on the BLB 109 is pulled down by such a discharge path, the pull-down transistor M4 may remain turned off. As such, the BL 107 and the BLB 109 may respectively present a voltage level to produce a large enough voltage difference between the BL 107 and BLB 109. Accordingly, a sensing amplifier, coupled to the BL 107 and BLB 109, can use a polarity of the voltage difference to determine whether the logical state of the data bit is a logical 1 or a logical 0.

To write the logical state of the data bit stored in the memory cell 100, the data to be written is applied to the BL 107 and/or the BLB 109. For example, BLB 109 is tied/shorted to 0V, e.g., ground 103, with a low-impedance connection. Then, the WL 105 is asserted, or activated, by an assert signal to a logical high, which turns on the access transistors M5 and M6. Once the access transistors M5 and M6 are turned on, based on the logical state of BLB 109, the node 110 may start to be discharged. For example, before M5 and M6 are turned on, the BLB 109 may present a voltage corresponding to the logical 0, and the node 110 may present a voltage corresponding to the complementary logical 1. In response to the access transistors M5 and M6 being turned on, a discharge path, starting from the node 110, through the access transistor M5 to ground 103, may be provided. Once the voltage level on the node 110 is pulled down below the Vth (threshold voltage) of the pull-down transistor M4, M4 may turn off and M3 may turn on, causing node 114 to be pulled up to CVDD 101. Once node 114 is less than a Vth from CVDD 101, M1 may turn off and M2 may turn off, causing node 110 to be pulled down to ground 103. Then, when the WL 105 is de-asserted, the logical state applied to the BL 107 and/or the BLB 109 has been stored in the memory cell 100.

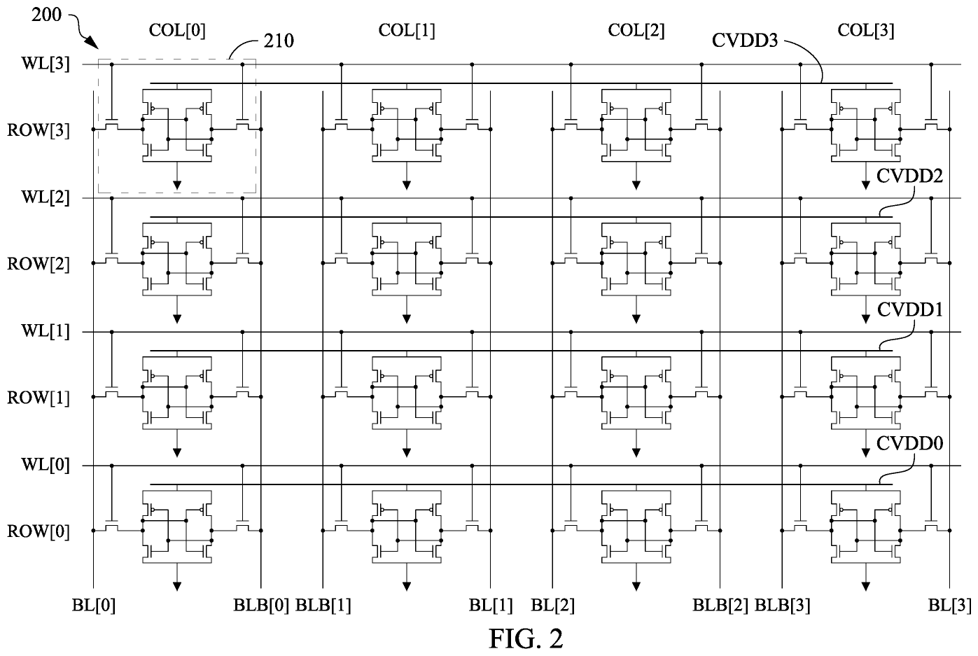

Referring to FIG. 2, an example circuit diagram of a memory device 200 (e.g., a memory array), according to the present disclosure, that includes a number of memory cells 210 is disclosed. In some aspects of the present disclosure, each of the memory cells 210 may be implemented as a 6T SRAM cell, e.g., the memory cell 100 as illustrated in the example of FIG. 1. Further, as will be discussed in further detail below, the transistors of each of the memory cells 210 may be laid out or otherwise formed based on a 4CPP architecture, which allows the memory cells 210 disposed along a configurable number of rows to be independently powered or otherwise driven with a respective supply voltage.

As shown, the memory array 200 includes sixteen memory cells 210 arranged in four columns (e.g., COL[0], COL[1], COL[2], and COL[3]) and four rows (e.g., ROW [0], ROW[1], ROW[2], and ROW[3]). These columns and rows intersect with one another, and each of the memory cells 210 is at an intersection of a corresponding pair of the columns and rows. Along each of the columns, a pair of bit line (BL) and complementary bit line (BLB) are disposed; and along each of the rows, a word line (WL) is disposed.

For example, along COL[0], the memory array 200 includes bit line BL[0] and complementary bit line BLB[0]; along ROW[0], the memory array 200 includes word line WL[0]; along COL[1], the memory array 200 includes bit line BL[1] and complementary bit line BLB[1]; along ROW[1], the memory array 200 includes word line WL[1]; along COL[2], the memory array 200 includes bit line BL[2] and complementary bit line BLB[2]; along ROW[2], the memory array 200 includes word line WL[2]; along COL[3], the memory array 200 includes bit line BL[3] and complementary bit line BLB[3]; and along ROW[3], the memory array 200 includes word line WL[3].

In various embodiments, the memory cells 210 in ROW[0], across all four columns COL[0] to COL[3] (which are coupled to respective pairs of bit lines and complementary bit lines), share a supply voltage, CVDD0; the memory cells 210 in ROW[1], across all four columns COL[0] to COL[3] (which are coupled to respective pairs of bit lines and complementary bit lines), share a supply voltage, CVDD1; the memory cells 210 in ROW[2], across all four columns COL[0] to COL[3] (which are coupled to respective pairs of bit lines and complementary bit lines), share a supply voltage, CVDD2; and the memory cells 210 in ROW[3], across all four columns COL[0] to COL[3] (which are coupled to respective pairs of bit lines and complementary bit lines), share a supply voltage, CVDD3.

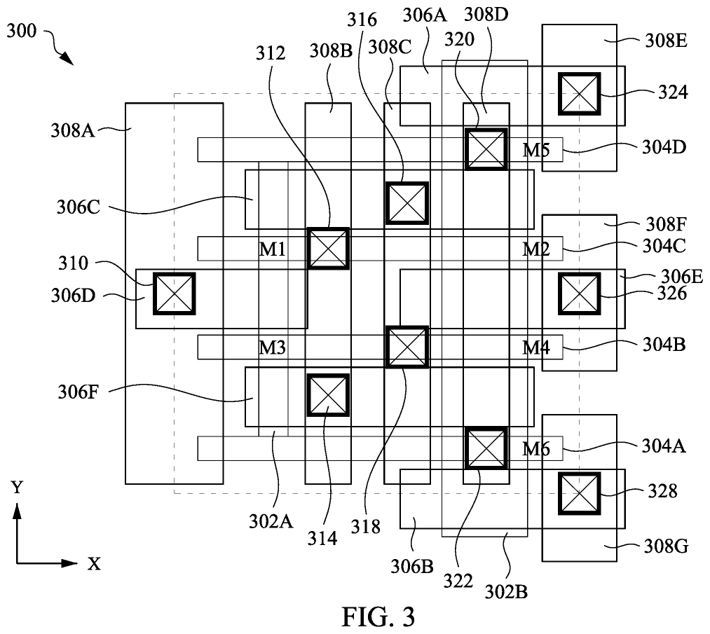

FIG. 3 illustrates an example layout schematic 300 of a memory cell (e.g., 100 in FIG. 1 or 210 in FIG. 2 which includes six transistors M1 to M6) configured in a 4CPP architecture, in accordance with various embodiments of the present disclosure. The layout 300 shown in FIG. 3 may be used to fabricate each memory cell of the memory device as a number of nanostructure transistors (e.g., GAA transistors, etc.), in some embodiments. However, it is understood that the layouts are not limited to fabricating nanostructure transistors. The layout 300 may be used to fabricate a memory cell with any of various other types of transistors such as, for example, nanowire transistors, nanosheet transistors, FinFETs, etc., while remaining within the scope of the present disclosure. The components of the layout 300 are the same or are substantially similar to those depicted in FIG. 1, and thus, some of the reference numerals may be reused in the discussion of FIG. 3.

As shown, the layout 300 includes patterns 302A and 302B extending along the Y direction, and patterns 304A, 304B, 304C, and 304D extending along the X direction. The patterns 302A and 302B are each configured to form an active region (e.g., a fin structure, a well, a protruding structure having alternately stacked silicon and silicon germanium layers, etc., which is sometimes referred to as an oxide diffusion (OD) region) over a substrate, and the patterns 304A to 304D are each configured to form a gate (e.g., a polysilicon gate, a metal gate, etc.) over the active regions. Accordingly, the patterns 302A to 302B may each be referred to as an active region, and the patterns 304A to 304D may each be referred to as a gate.

In some embodiments, the active region 302B may have n-type conductivity, and the active region 302A may have p-type conductivity. Based on the 4CPP architecture, each of the active regions 302A and 302 B is traversed or otherwise overlaid by the four gates 304A to 304D. As such, the six transistors, M1 to M6, of the memory cell can be formed by corresponding ones of the active regions and the gates. For example in FIG. 3, the pull-up transistor M1 can be formed by the active region 302A and the gate 304C; the pull-up transistor M3 can be formed by the active region 302A and the gate 304B; the access transistor M5 can be formed by the active region 302B and the gate 304D; the access transistor M6 can be formed by the active region 302B and the gate 304A; the pull-down transistor M2 can be formed by the active region 302B and the gate 304C; and the pull-down transistor M4 can be formed by the active region 302B and the gate 403B.

The layout 300 further includes patterns configured to form a number of interconnect structures to operatively (e.g., electrically) couple the transistors M1 to M6 from one to another, forming the circuit shown in FIGS. 1 and 2. For example, the layout 300 includes patterns 306A, 306B, 306C, 306D, 306E, and 306F, each of which is configured to form a source/drain interconnect structure (e.g., sometimes referred to as MD). The patterns 306A to 306F are hereinafter referred to as “MD 306A,” “MD 306B,” “MD 306C,” “MD 306D,” “MD 306E,” and “MD 306F,” respectively. These MDs 306A to 306F can extend along the lengthwise direction of the gates, in some embodiments. As such, the MDs 306A to 306F can couple the different transistors of a memory cell to each other, couple one or more of the transistors to a corresponding access line (e.g., a WL, a BL, a BLB), or couple one or more of the transistors to an interconnect structure carrying a supply voltage (e.g., CVDD, ground).

For example, the MD 306A can couple a first source/drain of the access transistor M5 to a BL, which can be formed by an upper level pattern (interconnect structure); the MD 306B can couple a first source/drain of the access transistor M6 to a BLB, which can be formed by another upper level pattern (interconnect structure); the MD 306C can couple both a second source/drain of the access transistor M5 and a first source/drain of the pull-down transistor M2 to a first source/drain of the pull-up transistor M1; the MD 306D can couple both a second source/drain of the pull-up transistor M1 and a first source/drain of the pull-up transistor M3 to a first supply voltage, which can be formed by yet another upper level pattern (interconnect structure); the MD 306E can couple both a second source/drain of the pull-down transistor M2 and a first source/drain of the pull-down transistor M4 to a second supply voltage, which can be formed by yet another upper level pattern (interconnect structure); and the MD 306F can couple both a second source/drain of the pull-down transistor M4 and a second source/drain of the access transistor M6 to a second source/drain of the pull-up transistor M3.

The layout 300 further includes patterns 308A, 308B, 308C, 308D, 308E, 308F, and 308G, each of which is configured to form an interconnect structures (e.g., an M0 track). The patterns 308A to 308G are hereinafter referred to as “M0 track 308A,” “M0 track 308B,” “M0 track 308C,” “M0 track 308D,” “M0 track 308E,” “M0 track 308F,” and “M0 track 308G,” respectively. In some embodiments, the M0 tracks 308A to 308D can each extend along the lengthwise direction of the active regions 302A-B, and be disposed over the gates 304A-D and MDs 306A-F.

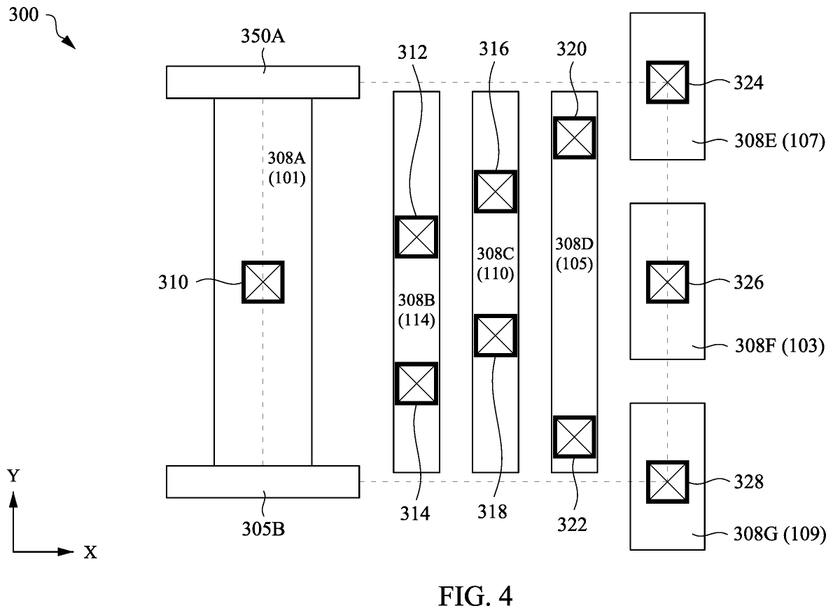

As such, the M0 tracks 308A, 308E, 308F, 308G, and 308D can be configured to function as the interconnect structure to carry the supply voltage CVDD (e.g., 101 of FIG. 1), the BL (e.g., 107 of FIG. 1), the interconnect structure to carry the ground voltage (e.g., 103 of FIG. 1), the BLB (e.g., 109 of FIG. 1), the WL (e.g., 105 of FIG. 1), respectively. Such correspondence is further shown in another schematic view of the layout 300 in FIG. 4 (where the active regions 302A-B, the gates 304A-D, and MDs 306A-F are intentionally omitted solely for purposes of clarity). In comparison with the M0 tracks 308A, 308E, 308F, 308G, and 308D that are configured to couple the transistors to other interconnect structures, the M0 tracks 308B and 308C may be configured as internal pads to couple different transistors of the memory cell. For example, the M0 track 308B can couple the gate of the pull-up transistor M1 to respective source/drains of the access transistor M6, pull-up transistor M3, and pull-down transistor M4, which may, for example, correspond to node 114 of FIG. 1. The M0 track 308C can couple the gate of the pull-up transistor M3 to respective source/drains of the access transistor M5, pull-up transistor M1, and pull-down transistor M2, which may, for example, correspond to node 110 of FIG. 1.

The layout 300 further includes patterns 310, 312, 314, 316, 318, 320, 322, 324, 326, and 328, each of which is configured to form a via structure. Specifically, the patterns 312, 318, 320, and 322 are each configured to couple a corresponding gate to an M0 track, which is sometimes referred to as VG. The patterns 312, 318, 320, and 322 are hereinafter referred to as “VG 312,” “VG 318,” “VG 320,” and “VG 322,” respectively. For example, the VG 312 can couple the gates of the pull-up transistor M1 and pull-down transistor M2 to the M0 track 308B. Still specifically, the patterns 310, 314, 316, 324, 326, and 328 are each configured to couple a corresponding MD to an M0 track, which is sometimes referred to as VD. The patterns 310, 314, 316, 324, 326, and 328 are hereinafter referred to as “VD 310,” “VD 314,” “VD 316,” “VD 324,” “VD 326,” and “VD 328,” respectively. For example, the VD 316 can couple the MD 306D (which connects to the sources of the pull-up transistors M1 and M3) to the M0 track 308A that is configured to carry the supply voltage CVDD.

In accordance with various embodiments of the present disclosure, the M0 track 308A, configured to carry a supply voltage CVDD, may have its ends, along its lengthwise direction, abutted by a pair of dielectric structures that can be formed by patterns 350A and 350B, respectively, as shown in FIG. 4. Such a dielectric structure may sometimes be referred to as “cut M0.” Accordingly, different rows of the memory cells may be arranged along the lengthwise direction of the M0 track 308A (e.g., the Y direction), where the memory cells in the same row may be arranged along a direction perpendicular to the lengthwise direction of the M0 track 308A (e.g., the X direction). As such, the M0 track 308A can be individually configured for a certain row.

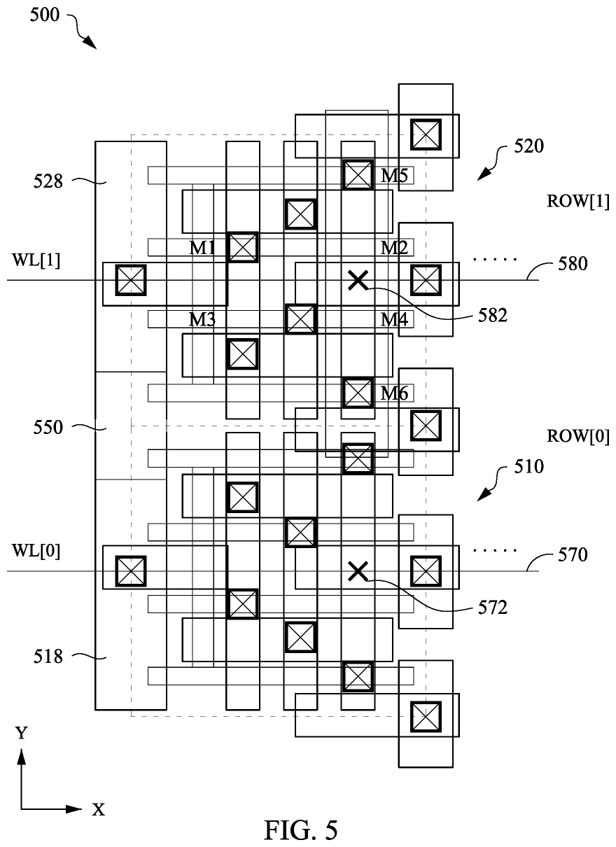

Based on such an embodiment, an example layout 500 having the memory cells disposed across a number of different rows is provided in FIG. 5. As shown, the layout 500 includes two memory cell layouts 510 and 520 abutted to each other along the Y direction. Each of the layouts 510 and 520 is substantially similar to the layout 300 of FIGS. 3-4, and thus, the corresponding description will not be repeated. In various embodiments, the memory cells 510 and 520 are disposed in respectively different rows of an array, e.g., ROW[0] and ROW[1]. Specifically, the memory cell 510 has a M0 track 518 configured to deliver a respective supply voltage CVDD0 to power the memory cell 510, and the memory cell 520 has a M0 track 528 configured to deliver a respective supply voltage CVDD1 to power the memory cell 520. The M0 tracks 518 and 528 are each substantially similar to the M0 track 308A (FIGS. 3 and 4). These two M0 tracks 518 and 528 are physically and electrically isolated from each other by a dielectric structure (cut M0) 550. Although not shown, it should be understood that on the other end of each of the M0 tracks 518 and 528 (along the Y direction), there should be another cut M0 formed to physically and electrically isolate the corresponding M0 track from the M0 track in another row.

The layout 500 further includes patterns 570 and 580, each of which is configured to form an interconnect structure (e.g., an M1 track). The patterns 570 and 580 are hereinafter referred to as “M1 track 570” and “M1 track 580,” respectively. In some embodiments, the M1 tracks 570 and 580, disposed one level above the M0 tracks, can each extend along a direction perpendicular to the lengthwise direction of the M0 tracks (e.g., the X direction). The M1 tracks 570 and 580 may each be configured as a global WL for the corresponding row. For example, the M1 track 570 can be configured as the global WL for ROW[0], and the M1 track 580 can be configured as the global WL for ROW[1]. The layout 500 further includes patterns 572 and 582 each of which is configured to form a via structure. Specifically, the patterns 572 and 582 are each configured to couple a corresponding M0 track to an M1 track, which is sometimes referred to as V0. The patterns 572 and 582 are hereinafter referred to as “V0 572” and “V0 582,” respectively.

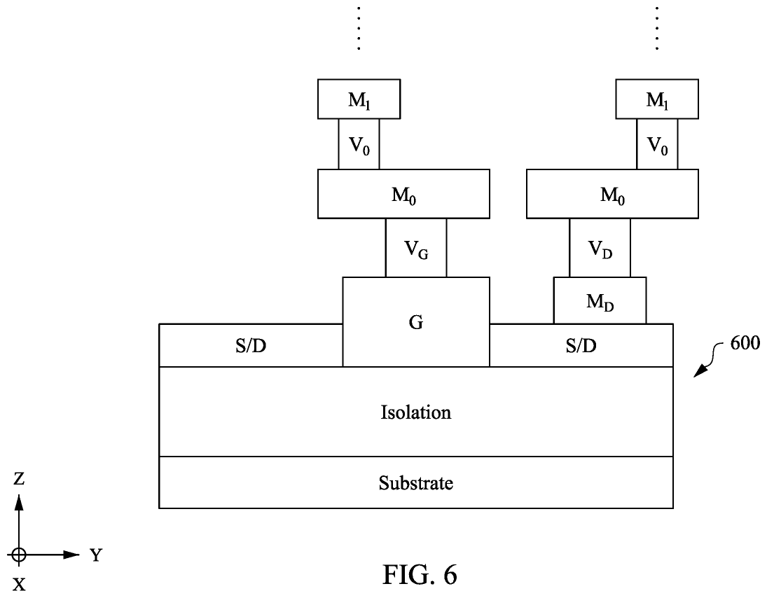

To further illustrate relative (e.g., vertical) arrangement of these structures, FIG. 6 depicts a cross-sectional view of a portion of a semiconductor device including a gate, a source, a drain, an MD, a VD, a VG, one or more M0 tracks, one or more V0s, and one or more M1 tracks. It should be understood that the cross-sectional view of FIG. 6 is provided as a general example to illustrate how an MD, a VD, a VG, one or more M0 tracks, one or more V0s, and one or more M1 tracks are vertically arranged with a transistor. Thus, the transistor shown in FIG. 6 can be any of the above-discussed pull-up transistor (e.g., M1, M3), pull-down transistor (e.g., M2, M4), or access transistor (e.g., M5, M6). As shown, a transistor 600 is formed over a substrate. The transistor 600 includes a gate, a pair of source and drain disposed on the opposite sides of the gate. The transistor 600 may be formed as a GAA transistor in which an active region is formed as a number of semiconductor layers vertically spaced from one another, with a portion of the active region overlaid by the gate functioning as its gate and with portions on the sides of the gate respectively functioning as its source and drain. Further, a portion of active region is embedded by an isolation region/structure. Over the transistor 600, the VG is connected to the gate, the MD is connected to at least one of the source or drain, the VD is connected to the MD, one of the M0 tracks is connected to the VG and coupled to one of the M1 tracks through one of the V0s, and another one of the M0 tracks is connected to VD and coupled to another of the M1 tracks through another of the V0s.

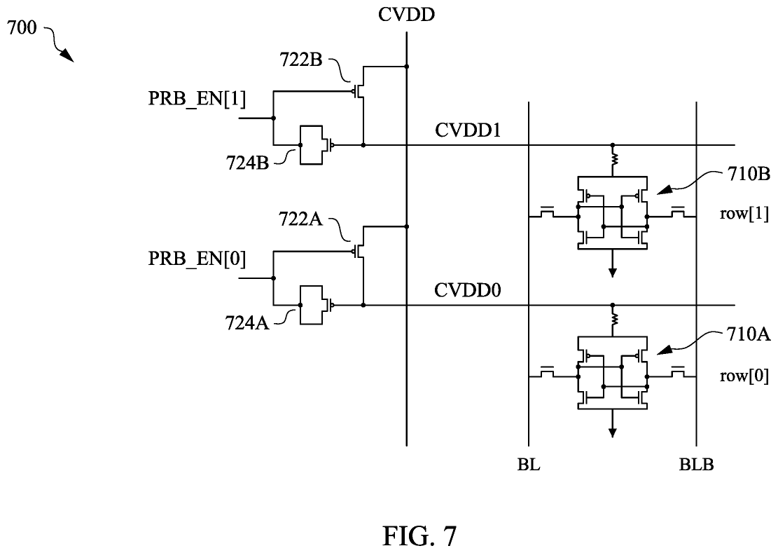

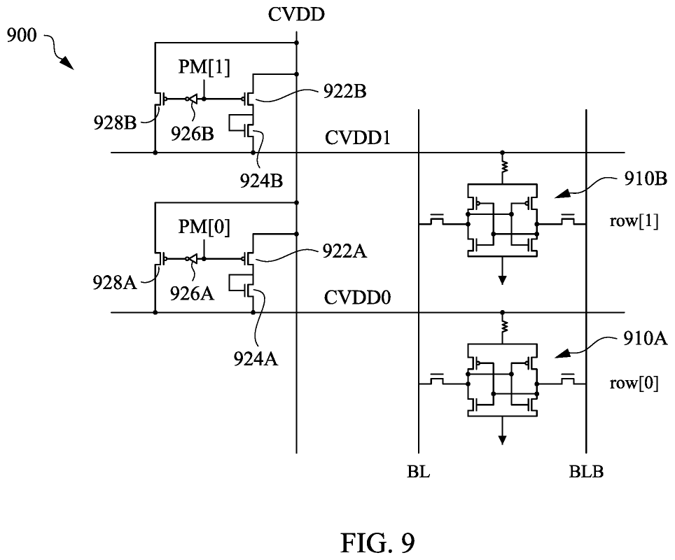

With the transistors of memory cells formed in the disclosed 4CPP architecture (e.g., layout 300, 500), the supply voltages received by every single row of the memory cells can be independently configured. FIGS. 7 and 9 respectively illustrate example circuit diagrams 700 and 900 of memory devices that have supply voltages individually configured for different rows. In each of FIGs, 7 and 9, the memory device is simplified to include two memory cells disposed along respectively different rows, ROW[0] and ROW[1]. However, it should be understood that the memory device of FIGS. 7 and 9 can include any number of memory cells, while remaining within the scope of the present disclosure.

Referring first to FIG. 7, memory cell 710A in ROW[0] and memory cell 710B in ROW[1] are both coupled to a common supply voltage, cell VDD (CVDD) or VDD. Specifically, the memory cell 710A is coupled to the common supply voltage CVDD through a number of boost components 722A and 724A, and a corresponding interconnect structure (e.g., the above-disclosed M0 track 308A) that allows the memory cells 710A to receive an individually configured supply voltage VDD (CVDDO), and the memory cells 710B is coupled to the common supply voltage CVDD through a number of boost components 722B and 724B, and a corresponding interconnect structure (e.g., the above-disclosed M0 track 308A) that allows the memory cells 710B to receive an individually configured supply voltage VDD (CVDD1). The boost components 722A-B may each be implemented as a PMOS transistor, and the boost components 724A-B may each be implemented as a capacitor.

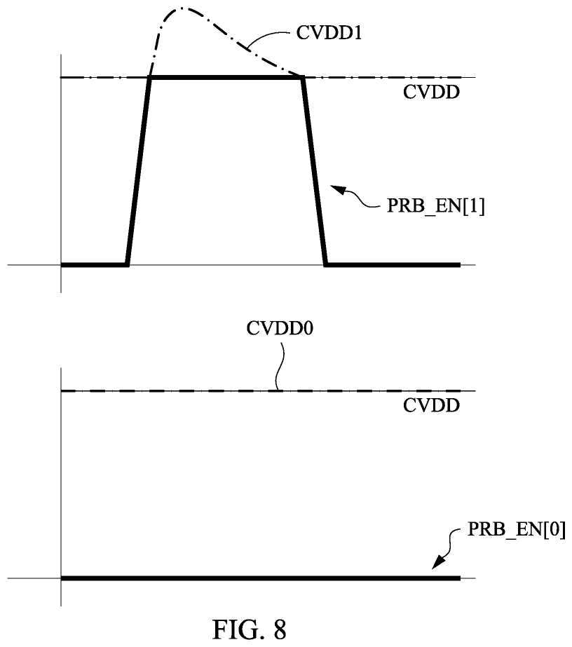

Further, a source of the PMOS transistor 722A/B is connected to the common supply voltage (CVDD) and a drain of the PMOS transistor 722A/B is connected between the capacitor 724A/B and the interconnect structure that carries the individually configured cell VDD, with a gate of the PMOS transistor 722A/B connected to a control signal PRB_EN. As such, when the control signal gating the PMOS transistor 722A in ROW[0], PRB_EN[0], is at logic low, the PMOS transistor 722A can be turned on, which causes CVDD0 to be equal to CVDD, as shown in FIG. 8. Concurrently, the control signal gating the PMOS transistor 722B in ROW[1], PRB_EN[1], can be configured at logic high. As such, the PMOS transistor 722B can be turned off, which can in turn cause CVDD1 to be boosted with charges stored by the capacitor 724B, as shown in FIG. 8. Such a boosted CVVD1 may enhance write efficiency of the memory cell 710B (or other memory cells along the same row, ROW[1]), while keeping the memory cells along the other row (e.g., ROW[0]) powered by the unchanged CVDD.

Referring then to FIG. 9, memory cell 910A in ROW[0] and memory cell 910B in ROW[1] are both coupled to a common supply voltage, cell VDD (CVDD) or VDD. Specifically, the memory cell 910A is coupled to common supply voltage CVDD through a number of retention components 922A, 924A, 926A, and 928A, and a corresponding interconnect structure (e.g., the above-disclosed M0 track 308A) that allows the memory cells 910A to receive an individually configured supply voltage VDD (CVDD0), and the memory cells 910B is coupled to common supply voltage CVDD through a number of retention components 922B, 924B, 926B, and 928B, and a corresponding interconnect structure (e.g., the above-disclosed M0 track 308A) that allows the memory cells 910B to receive an individually configured supply voltage VDD (CVDD1). The retention components 922A-B may each be implemented as a PMOS transistor, the retention components 924A-B may each be implemented as a diode-connected NMOS transistor, the retention components 926A-B may each be implemented as an inverter, and the retention components 928A-B may each be implemented as a PMOS transistor.

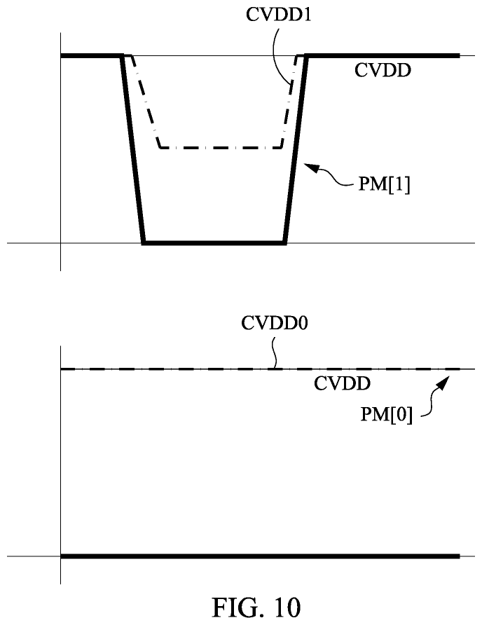

Further, a source of the PMOS transistor 922A/B is connected to the common supply voltage (CVDD) and a drain of the PMOS transistor 922A/B is connected to a tied gate-drain of the NMOS transistor 924A/B, with a gate of the PMOS transistor 922A/B connected to a control signal PM. A source of the NMOS transistor 924A/B is connected to the interconnect structure that carries the individually configured cell VDD. The inverter 926A/B can invert the control signal PM and gate the PMOS transistor 928A/B through such an inverted control signal. A source and drain of the PMOS transistor 928A/B are connected to CVDD and individually configured cell VDD, respectively. As such, when the control signal gating the PMOS transistor 922A in ROW[0], PM[0], is at logic high, the PMOS transistor 922A can be turned off while the PMOS transistor 928A can be turned on, which causes CVDD0 to be equal to CVDD, as shown in FIG. 10. Concurrently, the control signal gating the PMOS transistor 922B in ROW[1], PM[1], can be configured at logic low. As such, the PMOS transistor 922B can be turned on, which can in turn cause CVDD1 to be lower than CVDD with a voltage drop across the diode-connected NMOS transistor 924B, as shown in FIG. 10. Such a dropped CVVD1 may retain power of the memory cell 910B (or other memory cells along the same row, ROW[1]) which are not selected, while keeping the memory cells along the other row (e.g., ROW[0]), which are selected, powered by the unchanged CVDD.

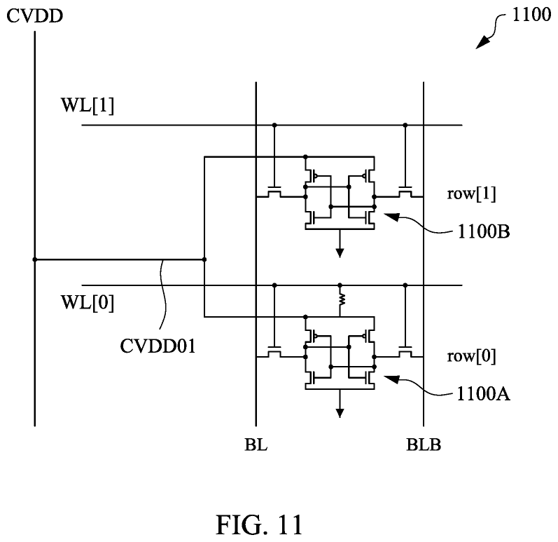

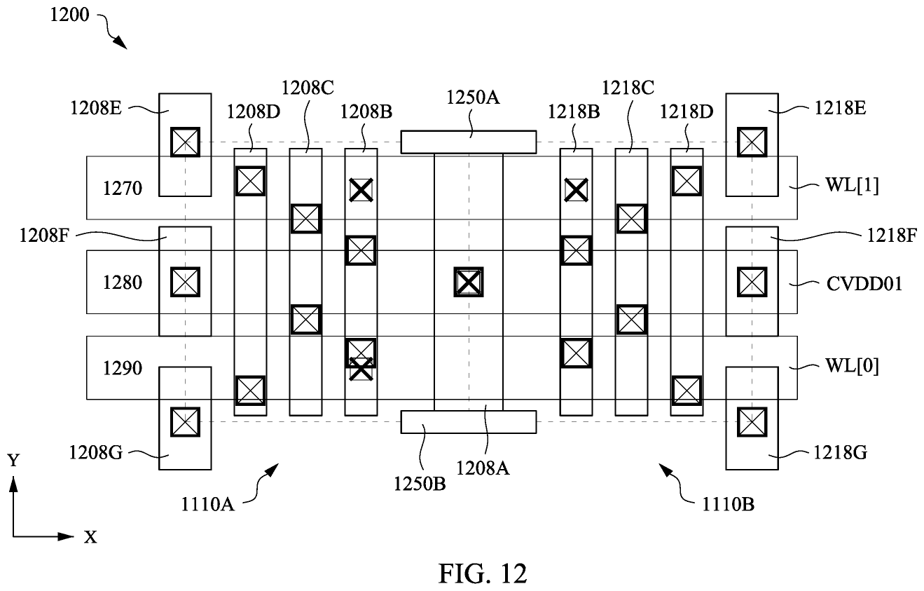

With the transistors of memory cells formed in the disclosed 4CPP architecture (e.g., layout 300, 500), the supply voltages received by every 2 rows of the memory cells can be independently configured. FIG. 11 illustrates an example circuit diagram 1100 of a memory device that has supply voltages individually configured for every 2 adjacent rows. FIG. 12 illustrates an example layout 1200 corresponding to the memory device shown in FIG. 11.

Referring first to FIG. 11, memory cell 1110A in ROW[0] and memory cell 1110B in ROW[1] are both coupled to a common supply voltage, cell VDD (CVDD). Specifically, the memory cell 1110A is coupled to the common supply voltage CVDD through a corresponding interconnect structure (e.g., the above-disclosed M0 track 308A) and the memory cell 1110B is coupled to the common supply voltage CVDD through the same corresponding interconnect structure, that allows both of the memory cells 1110A and 1110B to receive an individually configured supply voltage CVDD01.

Referring then to FIG. 12, the layout 1200 has two memory cells 1110A and 1110B abutted to each other. Each of the memory cells 1110A and 1110B is substantially similar to the layout 300 of FIGS. 3-4, and thus, the corresponding description will be briefly described (e.g., the active regions, gates, and MDs are intentionally omitted solely for purposes of clarity). As shown, the two memory cells 1110A and 1110B, disposed in two adjacent rows ROW[0] and ROW[1], respectively, are arranged next to each other along the lengthwise direction of the gates (e.g., the X direction), and can share a common M0 track that carries the supply voltage CVDD01.

For example, the memory cell 1110A includes M0 tracks 1208A, 1208B, 1208C, 1208D, 1208E, 1208F, and 1208G; and, while sharing the M0 track 1208A, the memory cell 1110B includes M0 tracks 1218B, 1218C, 1218D, 1218E, 1218F, and 1218G. In some embodiments, the M0 tracks 1208A, 1208B/1218B, 1208C/1218C, 1208D/1218D, 1208E/1218E, 1208F/1218F, and 1208G/1218G are substantially similar to the M0 tracks 308A, 308B, 308C, 308D, 308E, 308F, and 308G (FIGS. 3 and 4), respectively. For example, ends of the M0 track 1208A that delivers the supply voltage CVDD01 to the memory cells 1110A and 1110B are abutted with dielectric structures (cut M0s) 1250A and 1250B, respectively. Such cut M0s can electrically and physically isolate the M0 track 1208A from other similar M0 track delivering a supply voltage to other adjacent rows, in some embodiments. Based on the arrangement of the memory cells 1110A and 1110B shown in FIG. 12, the layout 1200 further includes M1 tracks 1270, 1280, and 1290 extending along a direction perpendicular to the lengthwise direction of the M0 tracks. In various embodiments, the M1 track 1270 can function as a global word line for ROW[1], e.g., WL[1]; the M1 track 1290 can function as a global word line for ROW[0], e.g., WL[0]; and the M1 track 1280 can function as a global interconnect structure carrying CVDD01 for both of ROW[0] and ROW[1].

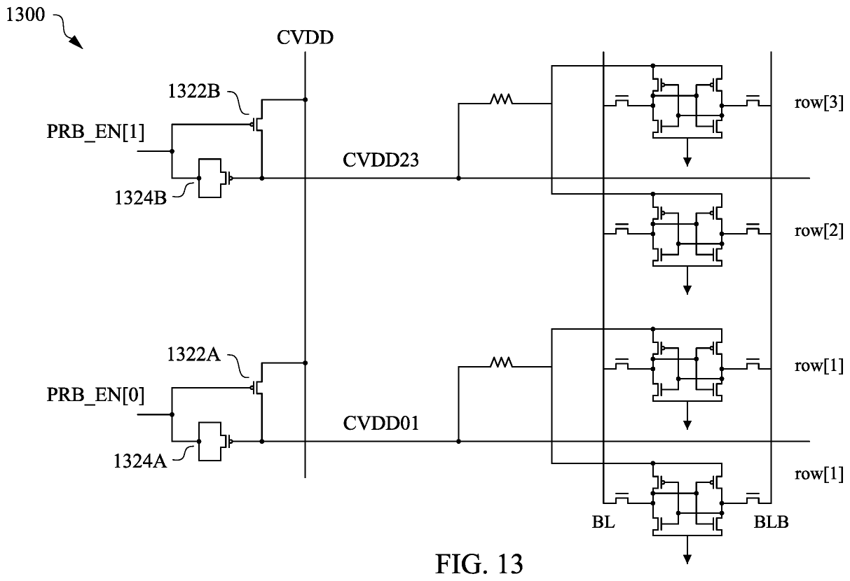

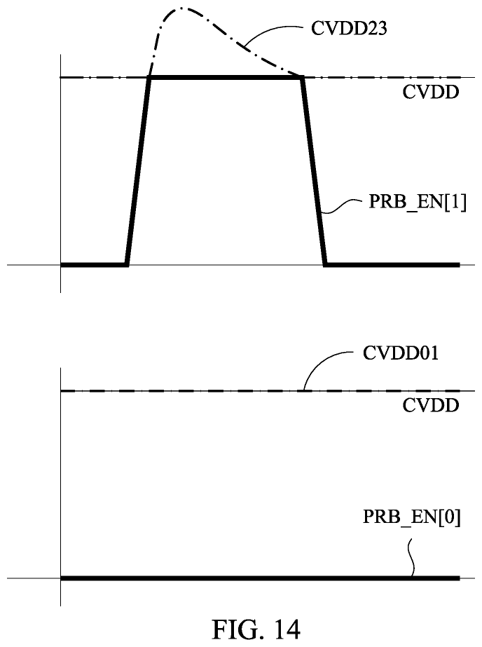

FIG. 13 illustrates an example circuit diagram 1300 that is substantially similar to the circuit diagram 700 of FIG. 7, except that each set of boost components may be shared by every 2 rows. For example, boost components 1322A and 1324A (which are similar to the boost components 722A/B and 724A/B, respectively) are shared by ROW[0] and ROW[1], and boost components 1322B and 1324B (which are similar to the boost components 722A/B and 724A/B, respectively) are shared by ROW[2] and ROW[3]. As such, supply voltage CVDD01 delivered to ROW[0] and ROW[1] and supply voltage CVDD23 delivered to ROW[2] and ROW[3] can be independently configured. For example in FIG. 14, CVDD 23 can be independently boosted (with PRB_EN[1] raised to high), while CVDD01 remains substantially unchanged (with PRB_EN[0] remaining at low).

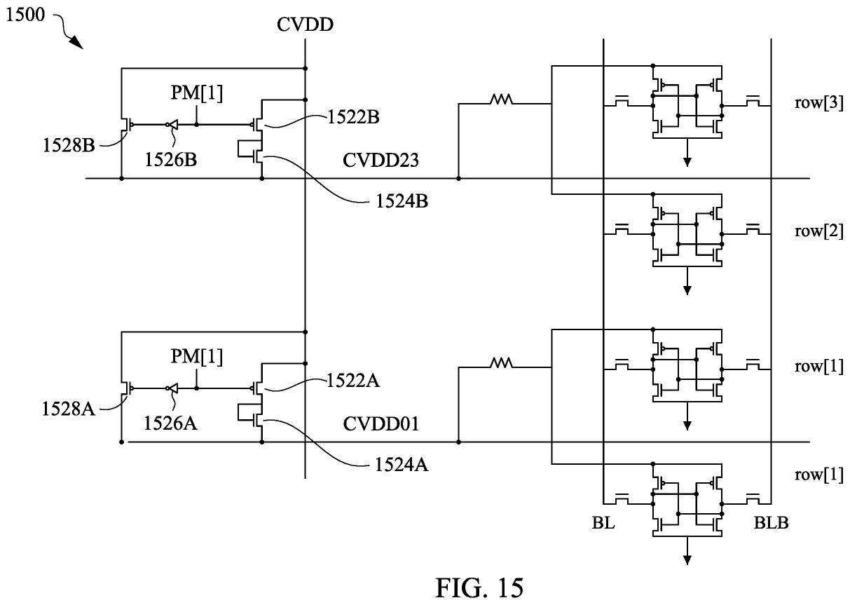

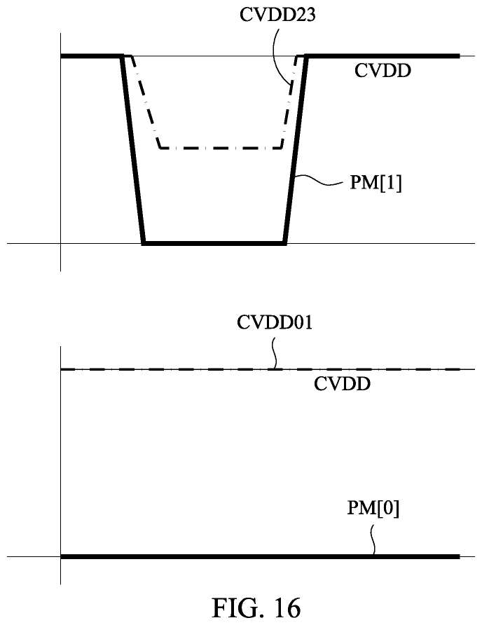

FIG. 15 illustrates an example circuit diagram 1500 that is substantially similar to the circuit diagram 900 of FIG. 9, except that each set of retention components may be shared by every 2 rows. For example, retention components 1522A, 1524A, 1526A, and 1528A (which are similar to the retention components 922A/B, 924A/B, 926A/B, and 928A/B, respectively) are shared by ROW[0] and ROW[1], and retention components 1522B, 1524B, 1526B, and 1528B (which are similar to the retention components 922A/B, 924A/B, 926A/B, and 928A/B, respectively) are shared by ROW[2] and ROW[3]. As such, supply voltage CVDD01 delivered to ROW[0] and ROW[1] and supply voltage CVDD23 delivered to ROW[2] and ROW[3] can be independently configured. For example in FIG. 16, CVDD 23 can be independently pulled down (with PM[1] toggled to low), while CVDD01 remains substantially unchanged (with PM[0] remaining at high).

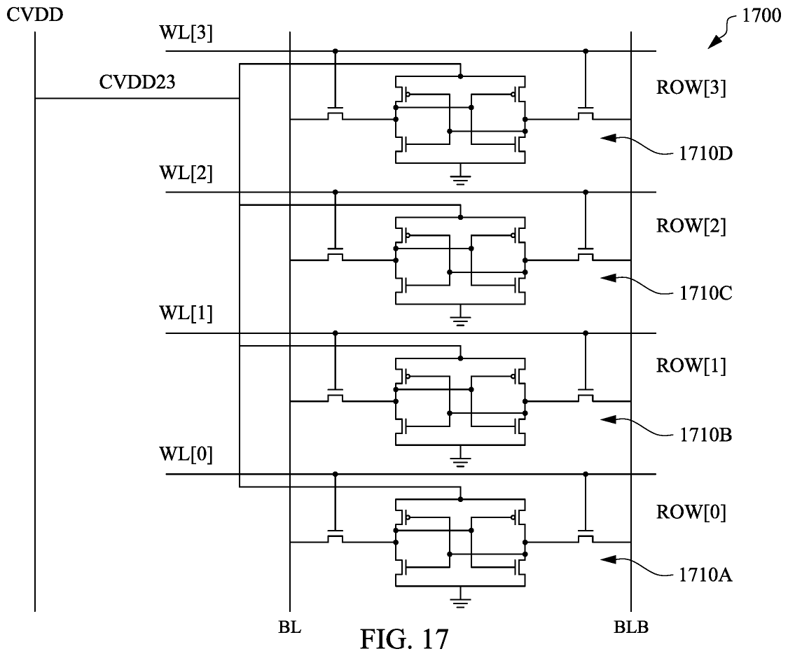

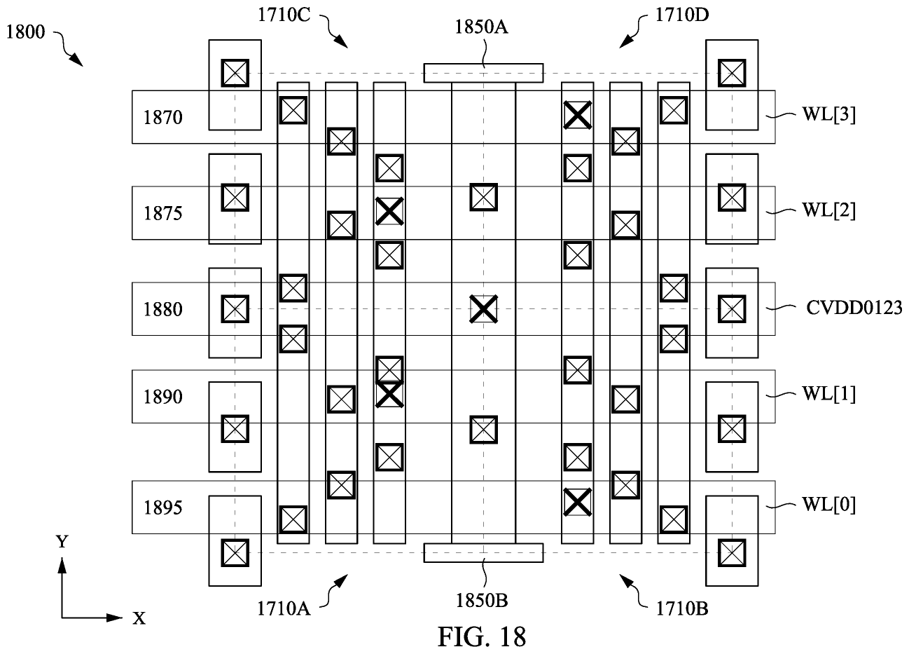

With the transistors of memory cells formed in the disclosed 4CPP architecture (e.g., layout 300, 500), the supply voltages received by every 4 rows of the memory cells can be independently configured. FIG. 17 illustrates an example circuit diagram 1700 of a memory device that has supply voltages individually configured for every 4 adjacent rows. FIG. 18 illustrates an example layout 1800 corresponding to the memory device shown in FIG. 17.

Referring first to FIG. 17, memory cell 1710A in ROW[0], memory cell 1710B in ROW[1], memory cell 1710C in ROW[2], and memory cell 1710D in ROW[3] are all coupled to a common supply voltage, cell VDD (CVDD). Specifically, the memory cell 1710A to 1710D are coupled to the common supply voltage CVDD through a same corresponding interconnect structure (e.g., the above-disclosed M0 track 308A), that allows four of the memory cells 1710A to 1710D to receive an individually configured supply voltage CVDD0123.

Referring then to FIG. 18, the layout 1800 has four memory cells 1710A to 1710D abutted to one another. Each of the memory cells 1710A to 1710D is substantially similar to the layout 300 of FIGS. 3-4, and thus, the corresponding description will be briefly described (e.g., the active regions, gates, and MDs are intentionally omitted solely for purposes of clarity). As shown, the memory cells 1710A and 1710B, disposed in two adjacent rows ROW[0] and ROW[1], respectively, are arranged next to each other along the lengthwise direction of the gates (e.g., the X direction), and the memory cells 1710C and 1710D, disposed in two adjacent rows ROW[2] and ROW[3], respectively, are arranged next to each other along the lengthwise direction of the gates (e.g., the X direction). Further, by abutting the memory cell 1710A to memory cell 1710C along the Y direction and abutting the memory cell 1710B to 1710D along the Y direction, the memory cells 1710A to 1710D can share a common M0 track that carries the supply voltage CVDD0123.

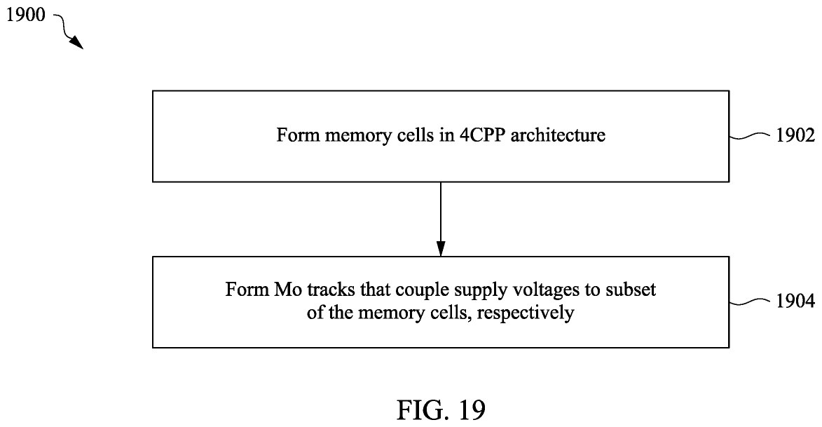

FIG. 19 illustrates a flowchart of an example method 1900 for forming a memory device, in accordance with some embodiments. In some embodiments, the operations of method 1900 are performed in the order depicted in FIG. 19. In some embodiments, the operations of method 1900 may be performed simultaneously and/or in an order other than the order depicted in FIG. 19.

The method 1900 starts with operation 1902 in which a number of memory cells are arranged over a substrate based on a 4CPP architecture. The memory cells may form a memory array having a number of rows and a number of columns intersecting with one another, where each memory cell is located at an intersection of a corresponding pair of the rows and columns. In various embodiments, each of the memory cells has a number of transistors operatively coupled to one another, e.g., six transistors as discussed above.

The substrate may be a semiconductor substrate, such as a bulk semiconductor, or the like, which may be doped (e.g., with a p-type or an n-type dopant) or undoped. The substrate 802 may be a wafer, such as a silicon wafer. Other substrates, such as a multi-layered or gradient substrate may also be used. In some embodiments, the semiconductor material of the substrate 802 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

Further at operation 1902, the memory cells can be formed on the substrate based on any of the above-discussed layouts, e.g., 300 (FIGS. 3-4), 500 (FIG. 5), 1200 (FIG. 12), or 1800 (FIG. 18). Specifically, the transistors of each of the memory cells can be formed as any of various types of transistors (e.g., GAA transistors, FinFETs, planar MOSFETs, etc.) based on such layouts. For example in FIG. 5, the transistors of the memory cells (corresponding to, e.g., 510, 520, etc.) are each formed with a 4CPP architecture, where each active region is traversed by four gates. Further, the memory cells along different rows (e.g., 510 and 520, respectively) are laterally abutted to one another along the Y direction, which can be in parallel with a lengthwise direction of the active regions of the transistors. For example in FIG. 12, similarly, the transistors of the memory cells (corresponding to, e.g., 1110A, 1110B, etc.) are each formed with the 4CPP architecture. Further, the memory cells along different rows (e.g., 1110A and 1110B, respectively) are laterally abutted to one another along the X direction, which can be in parallel with a lengthwise direction of the gates of the transistors.

The method 1900 continues to operation 1904 in which a number of interconnect structures (e.g., M0 tracks), that each can couple an individually configured supply voltage to a corresponding subset of the memory cells, are formed. Upon forming (and arranging) the transistors for each of the memory cells over the substrate (e.g., forming the respective active regions and gates), a number of interconnect structures can be formed over the transistors to operatively (e.g., electrically) couple different transistors within a single memory cell to each other and/or operatively (e.g., electrically) couple different memory cells to each other. Such interconnect structures can be disposed across a number of metallization layers over the transistors. A bottommost one of the metallization layers is sometimes referred to as “M0” and the interconnect structures disposed therein are sometimes referred to as “M0 tracks.”

In various embodiments, some of these M0 tracks can serve as a local connection pad to deliver an independently configured supply voltage (e.g., CVDDX) for a single memory cell or a plural number of memory cells. Different ones of these M0 tracks are electrically and physically isolated from one another by one or more dielectric structures (e.g., cut M0). As such, a subset of the memory cells that are arranged in a single row or a plural number of neighboring rows can receive (e.g., be powered by) an independently configured supply voltage. For example in FIG. 5, the M0 tracks 518 and 528, isolated from each other by the dielectric structure 550, can deliver separately configured supply voltages, CVDD0 and CVDD1, to the memory cells 510 and 520 (that are disposed in different rows), respectively.

For example in FIG. 12, the M0 track 1208A, isolated from other M0 tracks delivering respective supply voltages by the dielectric structures 1250A-B, can deliver an individually configured supply voltage, CVDD01, to both of the memory cells 1110A and 1110B (that are disposed in two neighboring rows, respectively).

In one aspect of the present disclosure, a memory device is disclosed. The memory device includes a plurality of memory cells disposed over a substrate and formed as an array that has a plurality of rows and a plurality of columns. Each of the memory cells is operatively coupled to a supply voltage through a corresponding one of a plurality of first interconnect structures. The plurality of first interconnect structures are electrically and physically isolated from one another.

In another aspect of the present disclosure, a memory device is disclosed. The memory device includes a plurality of memory cells disposed over a substrate and formed as an array that has a plurality of rows and a plurality of columns. Each of the plurality of memory cells includes a plurality of transistors. A first subset of the plurality of memory cells, that are disposed in first neighboring ones of the plurality of rows, are physically coupled to a corresponding one of a plurality of second interconnect structures that carries a supply voltage through a corresponding one of a plurality of first interconnect structures. The plurality of first interconnect structures extend along a first lateral direction in parallel with a lengthwise direction of a channel of each of the transistors of the memory cells, and the plurality of second interconnect structures, disposed above the plurality of first interconnect structures, extend along a second lateral direction perpendicular to the first lateral direction.

In yet another aspect of the present disclosure, a method for making memory devices is disclosed. The method includes forming an array including a plurality of memory cells over a substrate, wherein each of the plurality of memory cells comprises a plurality of transistors formed based on a four contacted polysilicon pitch (4CPP) architecture. The method includes forming a plurality of first interconnect structures over the plurality of transistors. The plurality of first interconnect structures are physically and electrically isolated from one another. The plurality of first interconnect structures are each configured to electrically couple a supply voltage to a subset of the memory cells that are arranged in a single one or neighboring ones of the rows.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a plurality of memory cells disposed over a substrate and formed as an array that has a plurality of rows and a plurality of columns;
wherein each of the memory cells is operatively coupled to a supply voltage through a corresponding one of a plurality of first interconnect structures;
wherein the plurality of first interconnect structures are electrically and physically isolated from one another.

2. The memory device of claim 1, wherein the memory cells are each formed based on a four contacted polysilicon pitch (4CPP) transistor architecture.

3. The memory device of claim 1, wherein a first one of the plurality of memory cells and a second one of the plurality of memory cells, that are disposed in a same one of the columns and in respectively different ones of the rows, have their respective first interconnect structures arranged along a lengthwise direction of the plurality of first interconnect structures.

4. The memory device of claim 3, wherein the first memory cell and second memory cell are operatively coupled to a respectively different ones of a plurality of second interconnect structures.

5. The memory device of claim 4, wherein a lengthwise direction of the plurality of second interconnect structures is perpendicular to the lengthwise direction of the plurality of first interconnect structures.

6. The method device of claim 5, wherein the plurality of second interconnect structures are disposed one layer above the plurality of first interconnect structures.

7. The memory device of claim 1, wherein the supply voltage corresponds to VDD.

8. The memory device of claim 1, wherein each of the memory cells includes a plurality of transistors, each of the plurality of transistors having its channel extending in a same direction as a lengthwise direction of the plurality of first interconnect structures.

9. A memory device, comprising:
a plurality of memory cells disposed over a substrate and formed as an array that has a plurality of rows and a plurality of columns;
wherein each of the plurality of memory cells includes a plurality of transistors;
wherein a first subset of the plurality of memory cells, that are disposed in first neighboring ones of the plurality of rows, are physically coupled to a corresponding one of a plurality of second interconnect structures that carries a supply voltage through a corresponding one of a plurality of first interconnect structures; and
wherein the plurality of first interconnect structures extend along a first lateral direction in parallel with a lengthwise direction of a channel of each of the transistors of the memory cells, and the plurality of second interconnect structures, disposed above the plurality of first interconnect structures, extend along a second lateral direction perpendicular to the first lateral direction.

10. The memory device of claim 9, wherein the transistors of each of the memory cells are formed based on a four contacted polysilicon pitch (4CPP) transistor architecture.

11. The memory device of claim 9, wherein a number of the first neighboring rows is equal to 2, and the corresponding first interconnect structure is interposed along a boundary of the first subset of memory cells.

12. The memory device of claim 11, wherein the first subset of memory cells are operatively coupled to respectively different ones of the plurality of second interconnect structures that are configured as a first word line and a second word line, respectively.

13. The memory device of claim 12, wherein the second interconnect structures that are configured as the first word line and second word line, respectively, are disposed on opposite sides of the second interconnect structure that is configured to carry the supply voltage.

14. The memory device of claim 9, wherein a second subset of the plurality of memory cells, that are disposed in second neighboring ones of the plurality of rows, are physically coupled to the second interconnect structures that carries the supply voltage through the corresponding first interconnect structure.

15. The memory device of claim 14, wherein a number of the first neighboring rows and a number of the second neighboring rows are each equal to 2, and the corresponding first interconnect structure is interposed along a boundary of the first subset of memory cells and also along a boundary of the second subset of memory cells.

16. The memory device of claim 15, wherein the first subset of memory cells are operatively coupled to respectively different ones of the plurality of second interconnect structures that are configured as a first word line and a second word line, respectively, and the second subset of memory cells are operatively coupled to respectively different ones of the plurality of second interconnect structures that are configured as a third word line and a fourth word line, respectively.

17. The memory device of claim 16, wherein the second interconnect structures that are configured as the first word line and second word line, respectively, are disposed on a first side of the second interconnect structure that is configured to carry the supply voltage, and the second interconnect structures that are configured as the third word line and fourth word line, respectively, are disposed on a second, opposite side of the second interconnect structure that is configured to carry the supply voltage.

18. A method for making memory devices, comprising:
forming an array including a plurality of memory cells over a substrate, wherein each of the plurality of memory cells comprises a plurality of transistors formed based on a four contacted polysilicon pitch (4CPP) architecture; and
forming a plurality of first interconnect structures over the plurality of transistors, wherein the plurality of first interconnect structures are physically and electrically isolated from one another, and wherein the plurality of first interconnect structures are each configured to electrically couple a supply voltage to a subset of the memory cells that are arranged in a single one or neighboring ones of the rows.

19. The method of claim 18, wherein the subset of memory cells are abutted to each other along a lateral direction perpendicular to a lengthwise direction of the plurality of first interconnect structures.

20. The method of claim 18, wherein a number of the neighboring rows is equal to 2 or 4.
